(19) United States
(12) Patent Application Publication
(10) Pub. No.: US 2006/0258054 A1
(43) Pub. Date: Nov. 16, 2006

(54) Method for producing free-standing carbon nanotube thermal pads

(75) Inventors: Lawrence S. Pan, Los Gatos, CA (US); Srinivas Rao, Saratoga, CA (US); Jim Protsenko, San Jose, CA (US); Gang Gu, Palo Alto, CA (US)

Correspondence Address: CARR & FERRELL LLP, 2200 GENG ROAD, PALO ALTO, CA, 94303, US

(73) Assignee: Molecular Nanosystems, Inc.

(21) Appl. No.: 11/433,184

(22) Filed: May 11, 2006

Related U.S. Application Data
(63) Continuation of application No. 60/709,611, filed on Aug. 19, 2005.
(60) Provisional application No. 60/680,262, filed on May 11, 2005.
(60) Provisional application No. 60/691,673, filed on Jun. 17, 2005.

(51) Int. Cl. H01L 21/00

(52) U.S. Cl. 438/122; 174/548

(57) ABSTRACT

Methods for producing carbon nanotube thermal pads comprise forming an array of carbon nanotubes on a catalyst layer on a substrate and releasing the array from the substrate. The carbon nanotubes are grown so that they are generally vertically aligned relative to the substrate. Releasing the array can include dissolving the substrate. Alternately, a release layer between the substrate and the catalyst layer can be employed. The release layer can be chemically removed, or can provide a low-strength interface that is easily pulled apart or sheared.

### CROSS-REFERENCE TO RELATED APPLICATIONS

This application claims the benefit of U.S. Provisional Patent Application No. 60/680,262 filed on May 11, 2005 and entitled “Carbon Nanotube-Based Thermal Pad,” U.S. Provisional Patent Application No. 60/691,673 filed on Jun. 17, 2005 and entitled “Carbon Nanotube-Based Thermal Pad,” and U.S. Provisional Patent Application No. 60/709,611 filed on Aug. 19, 2005 and entitled “Carbon Nanotube Based Interface Materials for Heat Dissipation Applications,” each of which is incorporated herein by reference in its entirety. This application is related to U.S. non-provisional patent application Ser. No. 11/______ filed on even date herewith and entitled “Methods for Forming Carbon Nanotube Thermal Pads” (attorney docket number PA3283US). This application is also related to U.S. non-provisional patent application Ser. No. 11/______ filed on even date herewith and entitled “Carbon Nanotube Thermal Pads” (attorney docket number PA3396US). This application is further related to U.S. non-provisional patent application Ser. No. 11/______ filed on even date herewith and entitled “Devices Incorporating Carbon Nanotube Thermal Pads” (attorney docket number PA3728US).

### STATEMENT REGARDING FEDERALLY SPONSORED RESEARCH OR DEVELOPMENT

This invention was made with United States Government support under Cooperative Agreement No. 70NANB2H3030 awarded by the Department of Commerce's National Institute of Standards and Technology. The United States has certain rights in the invention.

### BACKGROUND OF THE INVENTION

1. Field of the Invention

The present invention relates generally to the field of semiconductor packaging and more particularly to methods for forming structures that employ carbon nanotubes for thermal dissipation.

2. Description of the Prior Art

A carbon nanotube is a molecule composed of carbon atoms arranged in the shape of a cylinder. Carbon nanotubes are very narrow, on the order of nanometers in diameter, but can be produced with lengths on the order of hundreds of microns. The unique structural, mechanical, and electrical properties of carbon nanotubes make them potentially useful in electrical, mechanical, and electromechanical devices. In particular, carbon nanotubes possess both high electrical and thermal conductivities in the direction of the longitudinal axis of the cylinder. For example, thermal conductivities of individual carbon nanotubes of 3000 W/m-° K and higher at room temperature have been reported.

The high thermal conductivity of carbon nanotubes makes them very attractive materials for use in applications involving heat dissipation. For example, in the semiconductor industry, devices that consume large amounts of power typically produce large amounts of heat. Following Moore's Law, chip integration combined with die size reduction results in an ever increasing need for managing power density. The heat must be efficiently dissipated to prevent these devices from overheating and failing. Presently, such devices are coupled to large heat sinks, often through the use of a heat spreader. Additionally, to allow for differences in coefficients of thermal expansion between the various components and to compensate for surface irregularities, thermal interface materials such as thermal greases are used between the heat spreader and both the device and the heat sink. However, thermal greases are both messy and require additional packaging, such as spring clips or mounting hardware, to keep the assembly together, and thermal greases have relatively low thermal conductivities.

Therefore, what is needed are better methods for attaching heat sinks, sources, and spreaders that provides both mechanical integrity and improved thermal conductivity.

### SUMMARY

An exemplary method of forming a thermal pad comprises providing a substrate having a planar surface, forming a release layer on the planar surface, forming a catalyst layer on the release layer, forming an array of vertically aligned carbon nanotubes on the catalyst layer, and releasing the array of carbon nanotubes from the substrate. Releasing the array can include, for example, lifting the array off of the substrate with an adhesive layer, applying a shear force across the separation layer, or dissolving the release layer. Where releasing the array includes applying a shear force, the shear force can be applied mechanically or thermally by changing the temperature. Here, a difference in the coefficients of thermal expansion between the release layer and either the substrate, the catalyst layer, or some other layer between the two, creates the necessary shear force with the change of temperature to delaminate the array from the substrate. Advantageously, when the array is released, the newly freed surface is essentially as smooth as the planar surface of the substrate. The method can also comprise forming a surface layer, such as of copper, on the release layer before forming the catalyst layer. After release, the surface layer becomes one side of the thermal pad.

Another exemplary method of forming a thermal pad comprises providing a substrate having a planar surface, forming a surface layer on the planar surface, forming a catalyst layer on the surface layer, forming an array of vertically aligned carbon nanotubes on the catalyst layer, and dissolving the substrate. The surface layer, in some embodiments, can include copper, zinc, aluminum, nickel, or silicon carbide, depending on the intended use of the thermal pad. For example, the surface composition can be selected to match a composition of a surface to which the thermal pad is intended to be mated. Dissolving the substrate can include etching the substrate with an acid such as hydrofluoric acid. In some embodiments, the substrate is segmented into coupons before the substrate is dissolved, and in some of these embodiments the coupon is attached to a heat management aid, such as a heat spreader or heat sink, or to a semiconductor die before dissolving the substrate.

Still another exemplary method of forming a thermal pad comprises providing a substrate having a planar surface, forming a catalyst layer on the planar surface, forming an array of vertically aligned carbon nanotubes on the catalyst layer, and detaching the first end of the array from the catalyst layer. Detaching the first end of the array from the catalyst layer can include etching the carbon nanotubes at the first end of the array. Etching the carbon nanotubes can include subjecting the array to a heated atmosphere including hydrogen gas and water vapor.

Each of the various exemplary methods can further comprise additional steps relating to forming the catalyst layer, such as forming a barrier layer and/or an interface layer before forming the catalyst layer. Likewise, each exemplary method can include steps such as infiltrating the array with a matrix material, patterning the catalyst layer, metallizing the exposed end of the array, or attaching the exposed end to a foil. These and other variations are disclosed in the following detailed description.

### BRIEF DESCRIPTION OF DRAWINGS

FIG. 1 shows a cross-sectional view of a partially completed thermal pad on a substrate according to an exemplary embodiment of the invention. The order of the layers, from bottom to top, serves to illustrate exemplary methods of forming the thermal pad.

FIG. 2 shows a cross-sectional view of the thermal pad of FIG. 1 after separation from the substrate.

FIG. 3 shows a cross-sectional view of a partially completed thermal pad on a substrate according to another exemplary embodiment of the invention. The order of the layers, from bottom to top, serves to illustrate further exemplary methods of forming the thermal pad.

FIG. 4 shows a cross-sectional view of the thermal pad of FIG. 3 after separation from the substrate.

FIG. 5 shows a top view of a partially completed thermal pad formed on a semiconductor wafer and the same wafer after dicing into coupons, according to an exemplary embodiment of the invention.

FIG. 6 shows a cross-sectional view of a partially completed thermal pad on a substrate according to still another exemplary embodiment of the invention. The order of the layers, from bottom to top, serves to illustrate further exemplary methods of forming the thermal pad.

FIG. 7 shows a cross-sectional view of the thermal pad of FIG. 6 after separation from the substrate.

FIGS. 8-15 show cross-sectional views of additional processing steps that can be performed on the partially completed thermal pads of FIGS. 1, 4, and 7 prior to release, according to various embodiments of the invention.

### DETAILED DESCRIPTION OF THE INVENTION

The present invention provides methods for fabricating free-standing carbon nanotube-based thermal pads. The various methods described herein provide free-standing thermal pads by forming the pads on a substrate from which the thermal pads can be later released. The thermal pads are characterized by an array of generally aligned carbon nanotubes where the direction of alignment is essentially perpendicular to the surfaces of array. The alignment of the nanotubes allows the array to provide excellent thermal conduction in the direction of alignment. Accordingly, a thermal pad between a heat source and a heat sink provides a thermally conductive interface therebetween.

Some thermal pads are characterized by at least one, and in some instances, two very smooth surfaces. A thermal pad with a sufficiently smooth surface can adhere to another very smooth surface, such as the backside surface of semiconductor die, much like two microscope slides will adhere to each other. Surfaces of thermal pads, whether very smooth or not, can also be attached to an opposing surface with a metal layer, for example with solder, indium, or silver. Advantageously, some thermal pads are also characterized by a degree of flexibility and pliability. This can make it easier to work with the thermal pads in assembly operations and allows the thermal pads to conform to opposing surfaces that are curved or irregular.

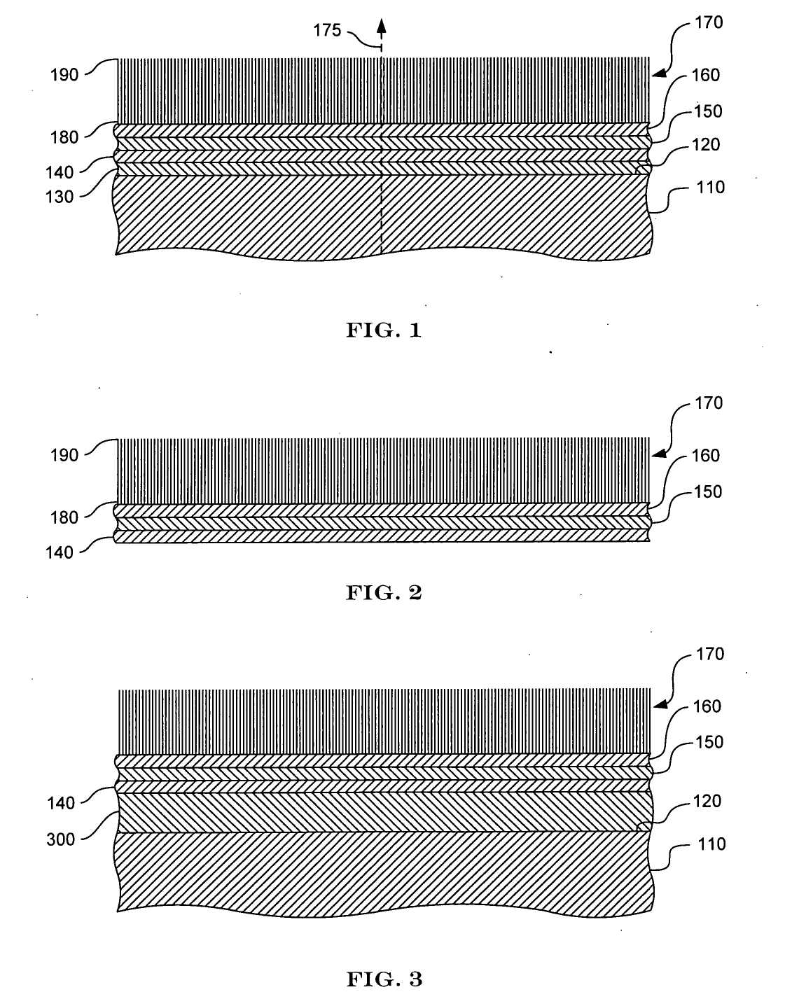

FIGS. 1 and 2 illustrate an exemplary method of forming a free-standing thermal pad. As shown by FIG. 1, a substrate 110 with a generally planar surface 120 is initially provided. Next, a separation layer 130 is formed on the planar surface 120. The method can also include forming an optional barrier layer 140 either before or after forming the separation layer 130. An optional interface layer 150 is formed over the separation layer 130, and over the barrier layer 140, if present.

Next, a catalyst layer 160 is formed. The catalyst layer 160 can be formed either directly on the separation layer 130, on the barrier layer 140, or on the interface layer 150. After the catalyst layer 160 has been formed, an array 170 of carbon nanotubes is formed on the catalyst layer 160. The array 170 is formed such that the carbon nanotubes are generally aligned in a direction 175 perpendicular to the planar surface 120. The array 170 includes a first end 180 attached to the catalyst layer 170 and a second end 190 opposite the first end 170.

Examples of a suitable substrate 110 include polished silicon and gallium arsenide wafers. Either can provide an atomically smooth planar surface 120 on which to form the successive layers 130-170. An example of a suitable separation layer 130 is nickel oxide. A nickel oxide separation layer 130 can be formed by depositing and then passivating a nickel thin film to form a dense and continuous oxide film. The passivation can be achieved, for instance, by thermal oxidation, exposure to an oxygen plasma, or by exposure to a strong acid such as chromic acid. A suitable thickness for the nickel oxide separation layer 130 is about 100 Å.

Another suitable separation layer 130, where the substrate 110 is gallium arsenide, is aluminum arsenide. An aluminum arsenide separation layer 130 can be formed, for example, by metal oxide CVD (MOCVD), and a suitable thickness for such a film is about 500 Å. As an alternative to forming the separation layer 130 by deposition, the separation layer 130 can be formed by ion implantation into the substrate 110. For example, hydrogen ions can be implanted into silicon to form a silicon hydride layer that can readily delaminate from the silicon.

The purpose of the barrier layer 140 is to prevent diffusion between the substrate 110 and/or the separation layer 130 and the catalyst layer 160. Preventing such diffusion is desirable in those embodiments where either the substrate 110 or the separation layer 130 includes one or more elements that can poison the catalyst of the catalyst layer 160 and prevent nanotube growth. Examples of elements that are known to poison nanotube catalysis include nickel, iron, cobalt, molybdenum, and tungsten. Other materials, such as silicon, are not known to poison nanotube catalysis. An example of a suitable barrier layer 140 is a sputtered film of aluminum oxide with a thickness of at least 50 Å, and more preferably 100 Å. An appropriate thickness for the barrier layer 140 will depend both on the permeability of the selected material to the elements to be impeded and on the roughness of the planar surface 120, as rougher finishes require a thicker barrier layers 140.

The interface layer 150 is provided, where needed, to improve the catalyst layer 160 which, in turn, provides for higher quality nanotubes characterized by higher wall crystallinities and fewer defects. In some embodiments, a single layer can serve as both the barrier layer 140 and the interface layer 150. Again, a sputtered film of aluminum oxide with a thickness of at least 50 Å, and more preferably 100 Å, can be a suitable interface layer 150. Another suitable interface layer 150 includes silicon dioxide. It should be noted that too thick of an interface layer 150 can lead to cracking during thermal cycling due to mismatches in coefficients of thermal expansion between the interface layer 150 and the layer beneath.

In various embodiments, the catalyst layer 160 is formed either directly on the separation layer 130, on the barrier layer 140, or on the interface layer 150. After the catalyst layer 160 has been formed, an array 170 of carbon nanotubes is formed on the catalyst layer 160. The array 170 is formed such that the carbon nanotubes are generally aligned in a direction 175 perpendicular to the planar surface 120. The array 170 includes a first end 180 attached to the catalyst layer 160 and a second end 190 opposite the first end 180. Depending on the growth conditions and choice of catalyst, the carbon nanotubes can be single-walled or multi-walled. The density, diameter, length, and crystallinity of the carbon nanotubes can also be varied to suit various applications.

One general method for achieving carbon nanotube growth is to heat the catalyst layer 160 in the presence of a carbon-bearing gas. Examples of suitable catalysts and process conditions are taught, for example, by Erik T. Thostenson et al. in “Advances in the Science and Technology of Carbon Nanotubes and their Composites: a Review,” Composites Science and Technology 61 (2001) 1899-1912, and by Hongjie Dai in “Carbon Nanotubes: Opportunities and Challenges,” Surface Science 500 (2002) 218-214. It will be appreciated, however, that the present invention does not require preparing the carbon nanotubes by the catalysis methods of either of these references, and any method that can produce generally aligned carbon nanotubes extending from a surface is acceptable.

After the carbon nanotube array 170 has been formed, the thermal pad is removed from the substrate 110 at the separation layer 130, as shown in FIG. 2. It will be appreciated that the surface of the thermal pad, after release from the substrate 110, will be essentially as smooth as the surface of the substrate 110 on which the array 170 was formed, and therefore can be atomically smooth, or nearly so. As described below, further processing of the array 170 can occur either before or after separation from the substrate 110.

Separation can be accomplished mechanically, chemically, or through a combination of techniques. For instance, where the separation layer comprises nickel oxide and an adjoining layer includes copper, separation can occur by the application of a shear force. Some embodiments take advantage of differences in the coefficients of thermal expansion between the array 170 and the separation layer 130. In these embodiments, after the array 170 is formed and begins to cool, the mismatch in the coefficients of thermal expansion causes a stress to develop along the interface that can cause the array 170 to spontaneously detach, or to detach upon the application of very little force.

An adhesive tape can be applied to the second end 190, in some embodiments, to both pull the array 170 away from the separation layer 130 and to give the released thermal pad a backing layer. In some embodiments the adhesive tape becomes part of the completed thermal pad. In these thermal pads, suitable adhesive tapes can be either electrically insulating, such as with a Kapton backing, or metallized to be conductive, to allow the thermal pad to either electrically isolate a device or component, or provide a path to ground.

Alternatively, the separation layer 130 can be removed chemically by wet etching or a thermal treatment. Thermal treatments take advantage of differences in coefficients of thermal expansion between layers to cause delamination at the separation layer 130. Wet etching can be achieved with strong acids such as hydrofluoric acid to dissolve either silicon or silicon dioxide. For some applications less aggressive and more environmentally acceptable solvents are desirable. Water, for instance, can be used where the separation layer 130 comprises a water-soluble salt.

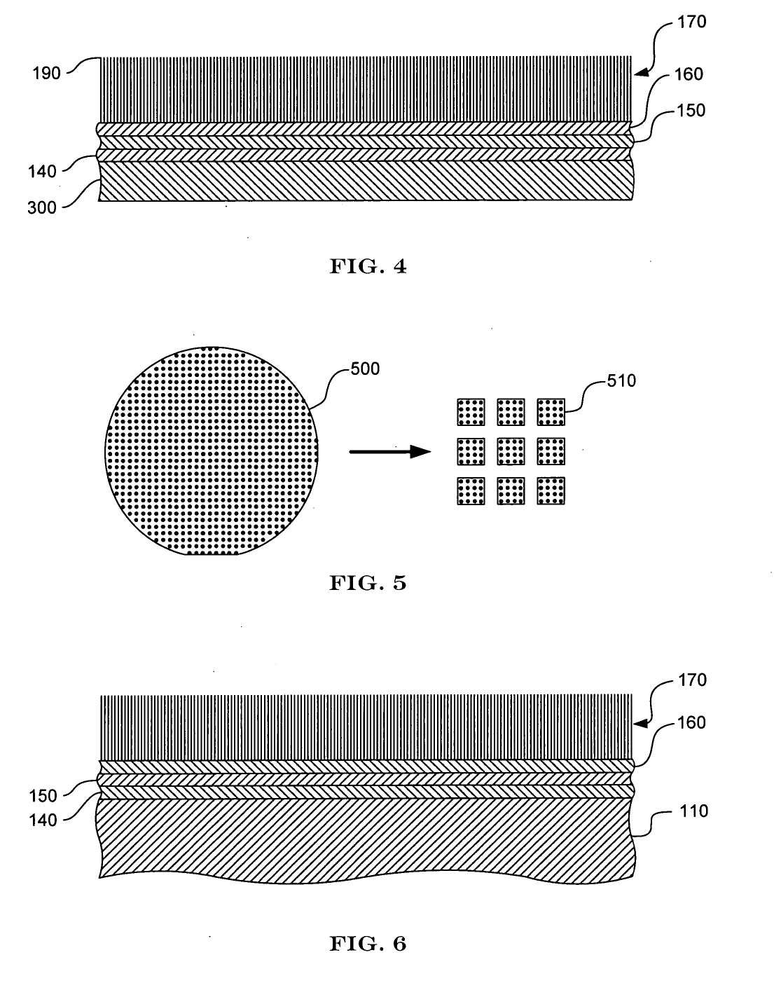

As shown in FIG. 3, another exemplary method includes a surface layer 300 intended to become part of the finished thermal pad after separation from the substrate 110. In FIG. 3, the surface layer 300 can be a thin layer of copper, for example. The particular material for the surface layer 300 can be chosen with respect to the intended use of the thermal pad. For instance, a metal for the surface layer 300 can be chosen to provide a superior bond to the material to which the thermal pad will be joined, or to match the coefficient of thermal expansion to that material. Zinc and silicon carbide are two examples of materials for the surface layer 300 where the thermal pad is to be attached to a silicon surface. Nickel and aluminum can be used for the surface layer 300 where the thermal pad will be joined to a nickel or aluminum coating on the surface of a thermal management aid (i.e., a heat sink or heat spreader).

In the example of FIG. 3, compared to that in FIGS. 1 and 2, the surface layer 300 is substituted for the separation layer 130 and the thermal pad is separated from the substrate 110 by dissolving the substrate 110, as shown in FIG. 4. For example, where the substrate 110 is a thinned silicon wafer, an acid such as hydrofluoric acid (HF) can be used to etch away the silicon, leaving the free-standing thermal pad bounded on one side by a smooth copper film. It will be appreciated that the surface layer 300 can also be added into the embodiment illustrated by FIG. 1. For instance, the surface layer 300 can be included between the separation layer 130 and the catalyst layer 160. In some of these embodiments, the surface layer 300 can also serve as a barrier layer 140.

Although the method of FIGS. 3 and 4 can produce a free-standing thermal pad, in some embodiments the free-standing thermal pad is never realized. Instead, the second end 190 is attached to a surface of another object such as a foil or a thermal management aid prior to the dissolution of the substrate 110. Methods for attaching the second end 190 to other objects are discussed further below.

In some of the embodiments represented generally by FIGS. 1-4, the substrate 110 is diced into sections or coupons before the thermal pad is separated from the substrate 110. FIG. 5 illustrates a top view of a wafer 500, including an array 170, and coupons 510 produced by dicing the wafer 500. With respect to the embodiments of FIGS. 1 and 2, dicing can occur prior to separating the thermal pad from the substrate 110. With respect to the embodiments of FIGS. 3 and 4, dicing can occur before the substrate 110 is dissolved. It will be understood that “dicing” is a term of art in the semiconductor field that is specific to cutting semiconductor wafers; however, the concept illustrated here is more general. Accordingly, a substrate 110 other than a semiconductor wafer can also be segmented prior to separating the substrate 110 from the thermal pad or before dissolving the substrate 110. Metal substrates 110 can be die cut, for example.

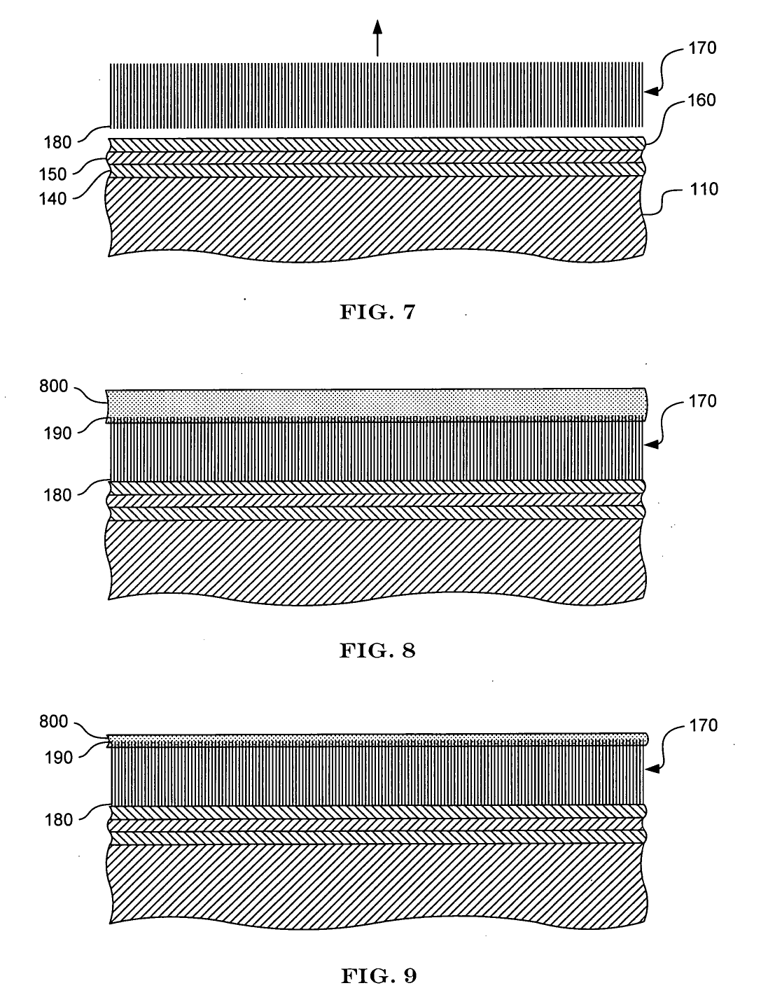

Yet another method for forming free-standing carbon nanotube thermal pads is illustrated in FIGS. 6 and 7. In FIG. 6 an array 170 is formed on a substrate 110 in a manner analogous to that shown by FIGS. 1 and 3, but without either the separation layer 130 or the surface layer 300. After the array 170 has been grown to the desired height, the environment (e.g., within a furnace or reactor) is modified to stop the growth of the carbon nanotubes and to etch the carbon nanotubes at the first end 180 of the array 170. More specifically, the process chemistry in the environment is changed by eliminating the gaseous carbon source to stop the growth process, and by introducing another gas that preferentially etches the carbon nanotubes at the interface with the catalyst layer 160.

An example of such a gas is a mixture of water vapor and hydrogen gas. In one embodiment, the array 170 is grown in a tube furnace. 50 standard cubic centimeters per minute (sccm) of argon gas is bubbled through a water bubbler to saturate the argon with water vapor. The argon saturated with water vapor is then mixed with 400 sccm of hydrogen gas and introduced into the tube furnace which is maintained at a temperature of 700° C. This atmosphere is maintained in the tube furnace for 5 minutes and causes the thermal pad to lift off of the substrate 110, as shown in FIG. 7.

The array 170 in any of the above embodiments can be further processed by the methods described below either prior to, or after, release from the substrate 110. In the following examples the embodiment shown in FIG. 6 is further modified, but it will be understood that the illustrated further processes can also be applied to the embodiments of FIGS. 1 and 3.

FIGS. 8 and 9 illustrate exemplary further steps to the embodiment of FIG. 6. In FIG. 8 a metal layer 800 is formed on the second end 190 of the array 170 so that the carbon nanotubes extend partially into the metal layer 800. A suitable metal for the metal layer 800 is copper. The metal layer 800 can be formed, for instance, by sputtering, evaporation, or electroplating. It should be noted that the metal layer 800 is not meant to infiltrate the entire array 170 but only to encapsulate the very ends of the carbon nanotubes and to extend a short distance above the second end 190. An appropriate thickness for the metal layer 800 will depend on the density of carbon nanotubes in the array 170 and the variation in their heights, but a minimum thickness for the metal layer 800 is on the order of 200 Å.

In some embodiments, forming the metal layer 800 includes applying a conformal coating to the ends of the carbon nanotubes with a wetting layer of a metal that promotes improved wetting of the metal layer 800 to the carbon nanotubes. Suitable wetting layer materials include palladium, chromium, titanium, vanadium, hafnium, niobium, tantalum, magnesium, tungsten, cobalt, zirconium, and various alloys of the listed metals. The wetting layer can be further coated by a thin protective layer, such as of gold, to prevent oxidation of the wetting layer. The wetting and protection layers may be achieved by evaporation, sputtering, or electroplating, for example. It should be noted that these conformal coatings merely conform to the ends of the carbon nanotubes and are not continuous films across the second end 190 of the array 170. Wetting and protection layers are described in more detail in U.S. non-provisional patent application Ser. No. 11/107,599 filed on Apr. 14, 2005 and titled “Nanotube Surface Coatings for Improved Wettability,” incorporated herein by reference in its entirety.

The metal layer 800 can be polished to increase the smoothness of the surface. FIG. 9 shows the structure of FIG. 8 after metal layer 800 has been polished. Metal layer 800 is thus thinner in FIG. 9 than in FIG. 8. Polishing the metal layer 800 can comprise chemical mechanical polishing (CMP) which also serves to planarize the surface. Copper is a good choice for the metal layer 800, in those embodiments that include CMP of the metal layer 800 in that CMP of copper has been refined in the semiconductor processing arts. In some embodiments, polishing the metal layer 800 continues until the second end 190 of the array 170 is exposed, while in other embodiments polishing is discontinued before that point is reached, as shown in FIG. 9.

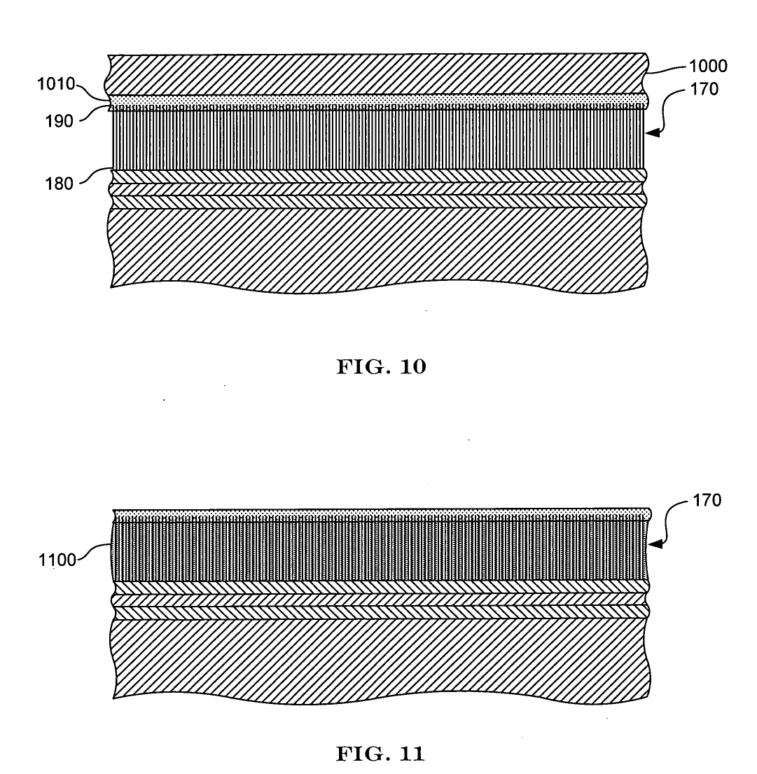

As shown in FIG. 10, instead of forming and polishing a metal layer 800, in other embodiments a thermal pad with a smooth surface is obtained by attaching a polished thin metal layer or foil 1000 to the array 170. A foil is distinguished from the thin metal layer in that the thin metal layer is self-supporting while the foil is not. Attaching the foil 1000 can include forming an attachment layer 1010 on the second end 190 of the array 170 so that the carbon nanotubes extend partially into the attachment layer 1010. Ideally, the attachment layer 1010 is formed of a low melting point metal or eutectic alloy such an indium, tin, bismuth, or a solder such as tin-silver, tin-lead, lead-silver, gold-germanium, or tin-antimony. The attachment layer 1010 may be formed by evaporation, sputtering, electroplating, or melting a thin sheet of the desired material, for example. As above, in some instances a wetting layer with or without a further protective layer can be applied as a conformal coating on the ends of the carbon nanotubes prior to forming the attachment layer 1010.

Copper and silver foils are examples of suitable foils 1000. The foil 1000 can be joined to the attachment layer 1010 by heating the foil 1000 while in contact with the attachment layer 1010 to briefly melt the attachment layer 1010 at the interface. In some embodiments, such as those in which the low melting point metal comprises indium, it can be advantageous to strip the native oxide layer from the attachment layer 1010 by cleaning the attachment layer 1010 with an acid such as hydrochloric acid prior to attaching the foil 1000.

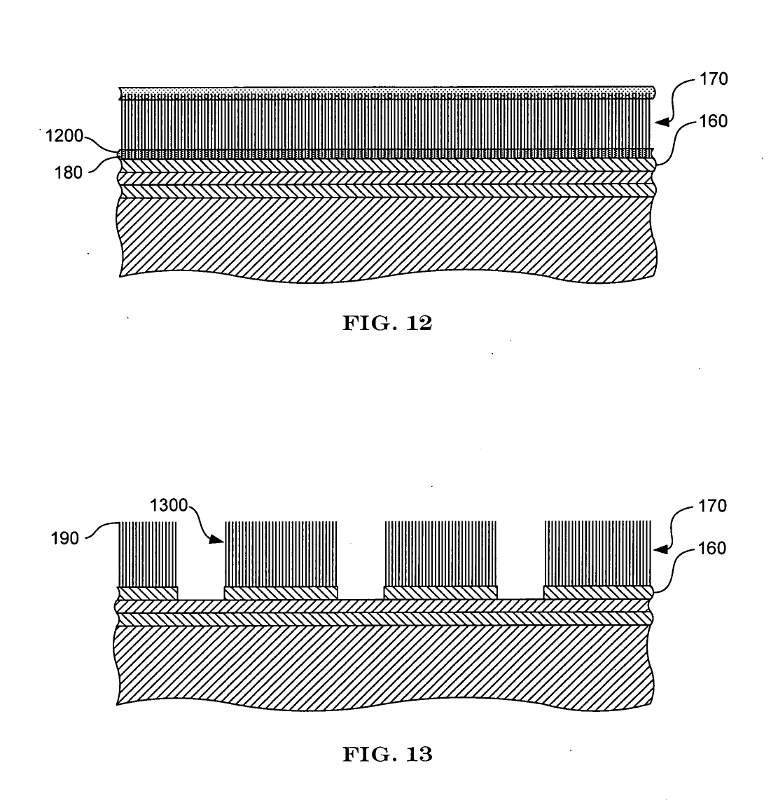

Each of the thermal pads shown in FIGS. 2, 4, and 7 is characterized by an array 170 of generally aligned carbon nanotubes with empty interstitial space between the carbon nanotubes. The empty interstitial space can be advantageous, in certain situations, as it provides the thermal pads with greater flexibility. In other embodiments, described below with reference to FIGS. 11 and 12, some or all of the interstitial space is filled.

For example, in FIG. 11 the interstitial space is filled by a matrix material 1100. Examples of matrix materials include metals and polymers. The interstitial space of the array 170 can be filled by a metal, for example, by electroplating. Injection molding can be used, for instance, to fill the interstitial space of the array 170 with a polymer such as parylene. Polymer injection molding into aligned nanotubes is taught by H. Huang, C. Liu, Y. Wu, and S. Fan in Adv. Mater. 2005, 17, 1652-1656. Both metal and polymers can be useful to provide additional structural support, while metals also provide some additional thermal conductivity.

FIG. 12 shows the interstitial space of the array 170 partially filled with a base metal layer 1200 that surrounds the carbon nanotubes at the first end 180 of the array 170 but otherwise leaves the interstitial space empty. The base metal layer 1200 can be formed of a metal such as copper by electroplating with the catalyst layer 160 serving as an electrode. The base metal layer 1200, like the matrix material 1100, is advantageous for further securing the array 170 to the catalyst layer 160. The base metal layer 1200 both provides this advantage while still leaving much of the interstitial space empty for greater flexibility of the thermal pad.

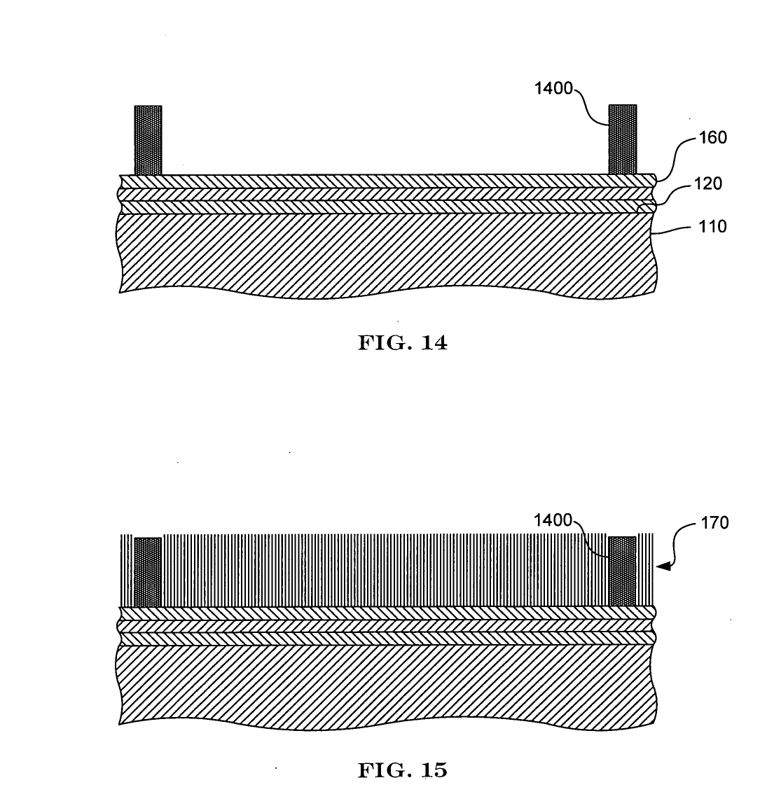

FIG. 13 illustrates yet another variation on the method of forming a thermal pad. In this example, the catalyst layer 160 is patterned, prior to forming the array 170, so that the carbon nanotubes of the array 170 grow in columns or bundles 1300. The catalyst layer 160 can be patterned, for example, by conventional masking techniques known to the semiconductor processing arts. Patterning the catalyst layer 160 to produce the bundles 1300 can be useful for those thermal pads that do not have a top layer such as metal layer 800 or foil 1000. When the second end 190 of the array 170 of such a thermal pad is joined to a surface, the taller bundles 1300, because of the spaces between the bundles 1300, are able to bend until the shorter bundles 1300 also contact the surface. In a similar manner, bundles 1300 can be beneficial to thermal pads even with a top layer to allow the top layer to deform to match the contour of a mating surface.

It should be noted that a continuous catalyst layer 160, as shown for example in FIG. 1, can be patterned to include a varying composition, thickness, or density of catalyst particles. Examples of such patterned catalyst layers are described in more detail in U.S. non-provisional patent application Ser. No. 11/124,005 filed on May 6, 2005 and titled “Growth of Carbon Nanotubes to Join Surfaces,” incorporated herein by reference in its entirety. Providing such patterning can be advantageous to vary aspects of the carbon nanotubes within the array 170 as a function of location. For example, where the thermal pad is intended to provide an interface with a backside of a semiconductor die with a known curvature, such as a convex shape, the heights of the carbon nanotubes can be varied from shorter at the center of the array 170 to longer at the edges. Likewise, a greater density of carbon nanotubes can be grown in areas of the array 170 in order to match the greater density to hot spots on the heat source.

FIGS. 14 and 15 illustrate still another variation on the method of forming a thermal pad. In this example, spacers 1400 are placed over the planar surface 120 of the substrate 110 before the array 170 is formed. In some embodiments, the spacers 1400 are placed on the catalyst layer 160 as shown in FIG. 14. Subsequently, the array 170 is formed, as shown in FIG. 15. Preferably, the array 170 is grown until a height of the array 170 exceeds a height of the spacers 1400. A thermal pad including spacers 1400 can be advantageous during assembly of the thermal pad within a device, package, or other structure. Not only can the spacers 1400 provide an appropriate spacing between two objects such as a heat source and a heat sink, but the spacers 1400 can also prevent damage to the carbon nanotubes of the array 170 by limiting the extent to which the carbon nanotubes can be deformed during handling and assembly. Suitable spacers are described in more detail in U.S. Non-Provisional patent application Ser. No. 11/124,005 noted above.

FIGS. 2, 4, and 7 as shown or as further modified by the processes of FIGS. 8-15 also represent different embodiments of finished thermal pads. The methods described herein are suitable to produce thermal pads with surface areas ranging from about 1 mm×1 mm, or less, to over 6″×6″. Arrays 170 of nanotubes can have thicknesses ranging from a few microns to over 1 mm. In particular, the thickness of the arrays 170 can be between 0.1 mm and 2 mm. Some thermal pads are characterized by a second end 190 with exposed nanotubes. Other thermal pads are characterized by a capped second end 190 where the capping is achieved with either an attached thin substrate or foil 1000, or a metal layer 800 that is either unfinished, polished, or polished and planarized. Additionally, any of these thermal pads can include carbon nanotubes grown in bundles 1300, and any can include spacers 1400.

Any of these thermal pads can include a matrix material 1100 that fills the interstitial space between the ends 180, 190 of the array 170. Similarly, any can include a base metal layer 1200 that only partially fills the interstitial space of the array 170 around the carbon nanotubes at the first end 180. Also, the interstitial space of any of these thermal pads can be left empty. As noted above, keeping the interstitial space empty improves flexibility. It should also be noted that keeping the interstitial space empty also improves compliance of the thermal pad to differential thermal expansion between opposing surfaces of two objects. The flexibility and pliability of some thermal pads allows them to be attached to curved surfaces in addition to generally flat surfaces.

Some thermal pads are fixedly attached to inflexible substrates, such as heat spreaders, where the second end 190 of the array 170 is meant to be attached to the surface of some other object. Other such thermal pads are free-standing components meant to be disposed between the opposing surfaces of a heat source and a heat sink.

A thermal pad having a second end 190 with exposed nanotubes can be joined to a surface of an object with a low melting point metal or eutectic alloy or a solder. One advantage of this method of joining the thermal pad to the surface is that neither the surface nor the second end 190 needs to be particularly smooth. Irregularities in either are filled by the low melting point metal, eutectic alloy, or solder. Reworking can be easily accomplished by low temperature heating.

A thermal pad having a second end 190 with exposed nanotubes can also be joined to a surface of an object simply by pressing the two together, known herein as “dry-pressing.” Dry pressing can be accomplished with or without the addition of pressure and heat. Modest elevated temperatures (e.g. 200-300° C.) and pressures (e.g., 10 to 100 psi) can be used. In some embodiments, sufficient heat is applied to soften or melt the surface of the object, for example, the copper surface of a heat sink, so that the ends of the carbon nanotubes push into the surface. In these embodiments it can be advantageous to perform the dry-pressing in a non-oxidizing environment such as an oxygen-free atmosphere. Dry-pressing can also comprise making the ends of the carbon nanotubes temporarily reactive. Here, plasma etching can be used, for example, to etch away amorphous carbon and/or any catalyst materials. Plasma etching can also create reactive dangling bonds on the exposed ends of the carbon nanotubes that can form bonds with the opposing surface. Dry pressing can also comprise anodic bonding, where a strong electric field pulls ions from the interface to create a strong bond.

Either end of a thermal pad that comprises a thin substrate, a foil 1000, an unfinished metal layer 800 (FIG. 8), or a polished metal layer 800 (FIG. 9) can be joined to a surface of another object in several ways. One method is to join the surface of the object with a metal having a melting point below the melting points of the object and the opposing surface of the thermal pad. For example, silver can be used to join a copper heat spreader with a palladium metal layer 800. Lower melting point metals such as indium and solder can also be used. In some embodiments the low melting point metal is cleaned with an acid such as hydrochloric acid to remove the native oxide. In the case of a thin substrate 200 comprising silicon, the silicon surface can be metallized with titanium and then silver to bond well to the low melting point metal.

In other instances, where both the surface of the object and the exposed surface of the thin substrate or foil are very smooth, the two can be held together by van der Waals attractions. In still other instances, both the surface of the object and the exposed surface of the thin substrate or foil are compositionally the same or very similar, for example where both comprise silicon. In this example, Si—Si bonds can spontaneously form between the two surfaces.

In the foregoing specification, the invention is described with reference to specific embodiments thereof, but those skilled in the art will recognize that the invention is not limited thereto. Various features and aspects of the above-described invention may be used individually or jointly. Further, the invention can be utilized in any number of environments and applications beyond those described herein without departing from the broader spirit and scope of the specification. The specification and drawings are, accordingly, to be regarded as illustrative rather than restrictive. It will be recognized that the terms “comprising,” “including,” and “having,” as used herein, are specifically intended to be read as open-ended terms of art.

What is claimed is:

1. A method of forming a thermal pad comprising:
providing a substrate having a planar surface;
forming a release layer on the planar surface;
forming a catalyst layer on the release layer;
forming an array of carbon nanotubes on the catalyst layer such that the carbon nanotubes are generally aligned in a direction perpendicular to the planar surface, the array characterized by a first end attached to the catalyst layer and a second end opposite the first end; and
releasing the array of carbon nanotubes from the substrate.

2. The method of claim 1 wherein the substrate comprises a silicon wafer.

3. The method of claim 1 wherein forming the release layer includes forming a nickel oxide layer.

4. The method of claim 1 wherein forming the release layer includes forming an aluminum arsenide layer.

5. The method of claim 1 wherein forming the release layer includes forming a water-soluble salt layer.

6. The method of claim 1 wherein releasing the array includes lifting the array off of the substrate with an adhesive layer.

7. The method of claim 1 wherein releasing the array includes applying a shear force across the separation layer.

8. The method of claim 7 wherein applying the shear force across the separation layer includes changing the temperature.

9. The method of claim 1 wherein releasing the array includes dissolving the release layer.

10. The method of claim 1 further comprising segmenting the substrate to form a coupon before releasing the array.

11. The method of claim 1 further comprising forming a surface layer on the release layer before forming the catalyst layer.

12. The method of claim 11 wherein the surface layer comprises copper.

13. A method of forming a thermal pad comprising:
providing a substrate having a planar surface;
forming a surface layer on the planar surface;
forming a catalyst layer on the surface layer;
forming an array of carbon nanotubes on the catalyst layer such that the carbon nanotubes are generally aligned in a direction perpendicular to the planar surface, the array characterized by a first end attached to the catalyst layer and a second end opposite the first end; and
dissolving the substrate.

14. The method of claim 13 wherein the surface layer includes a material selected from the group consisting of copper, zinc, aluminum, nickel, and silicon carbide.

15. The method of claim 13 wherein dissolving the substrate includes etching the substrate with an acid.

16. The method of claim 13 further comprising segmenting the substrate to form a coupon before dissolving the substrate.

17. The method of claim 16 further comprising attaching the coupon to a heat management aid or a semiconductor die before dissolving the substrate.

18. A method of forming a thermal pad comprising:
providing a substrate having a planar surface;
forming a catalyst layer on the planar surface;
forming an array of carbon nanotubes on the catalyst layer such that the carbon nanotubes are generally aligned in a direction perpendicular to the planar surface, the array characterized by a first end attached to the catalyst layer and a second end opposite the first end; and
detaching the first end of the array from the catalyst layer.

19. The method of claim 18 wherein detaching the first end of the array from the catalyst layer includes etching the carbon nanotubes at the first end of the array.

20. The method of claim 19 wherein etching the carbon nanotubes includes subjecting the array to a heated atmosphere including hydrogen gas and water vapor.

21. The method of claim 20 further comprising infiltrating the array with a matrix material.

22. The method of claim 20 further comprising attaching a metal foil to the second end of the array before detaching the first end of the array from the catalyst layer.
